(19) United States
(12) Patent Application Publication
(10) Pub. No.: US 2026/0319198 A1
(43) Pub. Date: Oct. 15, 2026

(54) CO-PACKAGED OPTICS CHIP MODULE

(71) Applicant: AUO Corporation, Hsinchu City (TW)

(72) Inventors: Min-Hsuan Chiu, Hsinchu City (TW); Wei-Ming Cheng, Hsinchu City (TW); Chung-Tao Chen, Hsinchu City (TW); Shu-Kai Hung, Hsinchu City (TW); Wan Heng Chang, Hsinchu City (TW); Sung-Yu Su, Hsinchu City (TW); Shih-Hsiung Lin, Hsinchu City (TW)

(73) Assignee: AUO Corporation, Hsinchu City (TW)

(21) Appl. No.: 19/340,880

(22) Filed: Sep. 26, 2025

(30) Foreign Application Priority Data
Apr. 10, 2025 (TW) 114113500

(51) Int. Cl. G02B 6/42; H10W 70/63; H10W 90/00

(52) U.S. Cl. CPC G02B 6/4246; G02B 6/4204; G02B 6/4239; G02B 6/428; H10W 70/635; H10W 90/701; H10W 90/724

(57) ABSTRACT

A co-packaged optical chip module includes a first chip, a first light emitting and receiving unit, a second chip, a second light emitting and receiving unit, and a first optical transmission element. The first optical transmission element includes a first light transmitting base, a first micro collimating lens, a first sealant, and a second light transmitting base. The first micro collimating lens is disposed on a first working area of the first light transmitting base. The first sealant is disposed on a first peripheral area of the first light transmissive base and surrounds the first micro collimating lens. The second light transmitting base is disposed opposite to the first light transmitting base. The first sealant connects the first light transmitting base and the second light transmitting base.

### CROSS-REFERENCE TO RELATED APPLICATION

This application claims the priority benefit of Taiwan application serial no. 114113500, filed on Apr. 10, 2025. The entirety of the above-mentioned patent application is hereby incorporated by reference herein and made a part of this specification.

### BACKGROUND

### Technical Field

The disclosure relates to a co-packaged optical chip module.

### Description of Related Art

With the rise of artificial intelligence (AI) applications, the number of graphics processing units (GPU)/central processing units (CPU) continues to increase and become a popular subject. As the number of chips increases, the data transmission distance between GPU/CPU, the transmission distance between GPU/GPU, and even the transmission distance between circuit boards are becoming further. However, the bandwidth of wires will reach the limit as the transmission distance increases, so how to use light transmission to replace wire transmission has become an important topic.

### SUMMARY

The disclosure provides a co-packaged optical chip module with good performance.

A co-packaged optical chip module of the disclosure includes a first chip, a first light emitting and receiving unit, a second chip, a second light emitting and receiving unit, and a first optical transmission element. The first light emitting and receiving unit is electrically connected to the first chip. The first light emitting and receiving unit includes at least one first light emitting element and at least one first light receiving element. The second light emitting and receiving unit is electrically connected to the second chip. The second light emitting and receiving unit includes at least one second light emitting element and at least one second light receiving element. The at least one first light emitting element of the first light emitting and receiving unit is configured to emit a first signal beam. The first signal beam is transmitted to the at least one second optical receiving element of the second light emitting and receiving unit through the first optical transmission element. The first optical transmission element includes a first light transmitting base, at least one first micro collimating lens, a first sealant, and a second light transmitting base. The first light transmitting base has a first working area and a first peripheral area surrounding the first working area. The at least one first micro collimating lens is disposed on the first working area of the first light transmitting base. The first sealant is disposed on the first peripheral area of the first light transmitting base and surrounds the at least one first micro collimating lens. The second light transmitting base is disposed opposite to the first light transmitting base. The first sealant connects the first light transmitting base and the second light transmitting base.

In an embodiment of the disclosure, the at least one first light emitting element includes multiple first light emitting elements, the at least one first light receiving element includes multiple first light receiving elements, the at least one first micro collimating lens includes multiple first micro collimating lenses, and the first micro collimating lenses of the first optical transmission element are respectively disposed corresponding to the first light emitting elements and the first light receiving elements.

In an embodiment of the disclosure, the first optical transmission element further includes a first protruding structure located between the first peripheral area of the first light transmitting base and the second light transmitting base. The first sealant is sandwiched between the first protruding structure and one of the first light transmitting base and the second light transmitting base.

In an embodiment of the disclosure, the first light transmitting base, the second light transmitting base, and the first sealant enclose to form a quasi-vacuum space.

In an embodiment of the disclosure, the first light transmitting base is closer to the first light emitting and receiving unit than the second light transmitting base, and a thickness of the first light transmitting base is less than a thickness of the second light transmitting base.

In an embodiment of the disclosure, the co-packaged optical chip module further includes a main circuit board and a first interposer substrate. The first interposer substrate is disposed between the first light emitting and receiving unit and the main circuit board. The first interposer substrate includes a base, at least one conductive layer, and at least one dielectric layer. The substrate is disposed on the main circuit board. The at least one conductive layer is disposed on the base and is electrically connected to the main circuit board. The at least one dielectric layer covers the at least one conductive layer. The first light emitting elements and the first light receiving elements are bonded to the at least one conductive layer of the first interposer substrate.

In an embodiment of the disclosure, the base of the first interposer substrate has multiple through holes. The first interposer substrate further includes multiple conductive objects respectively disposed in the through holes of the base of the first interposer substrate. The conductive objects are electrically connected to the at least one conductive layer of the first interposer substrate and the main circuit board.

In an embodiment of the disclosure, the co-packaged optical chip module further includes a second optical transmission element. The second optical transmission element includes a third light transmitting base, at least one second micro collimating lens, a second sealant, and a fourth light transmitting base. The third light transmitting base has a first working area and a first peripheral area surrounding the first working area. The at least one second micro collimating lens is disposed on the first working area of the third light transmitting base. The second sealant is disposed on the first peripheral area of the third light transmitting base and surrounds the at least one second micro collimating lens. The fourth light transmitting base is disposed opposite to the third light transmitting base. The second sealant connects the third light transmitting base and the fourth light transmitting base. Two ends of the optical fiber beam are respectively coupled to the first optical transmission element and the second optical transmission element.

In an embodiment of the disclosure, the first light transmitting base further has a second working area located outside the first working area. The first optical transmission element further includes at least one second micro collimating lens and at least one waveguide. The at least one second micro collimating lens is disposed on the second working area of the first light transmitting base. The first sealant further surrounds the at least one second micro collimating lens. The second light transmitting base of the first optical transmission element has an inner surface and an outer surface. The inner surface faces the at least one first micro collimating lens. The outer surface is opposite to the inner surface. The at least one waveguide is disposed on the outer surface of the second light transmitting base, and two ends of the at least one waveguide respectively correspond to the at least one first micro collimating lens and the at least one second micro collimating lens.

In an embodiment of the disclosure, there is a gap between the first light emitting and receiving unit and the second light emitting and receiving unit, and the at least one waveguide of the first optical transmission element spans across the gap.

In an embodiment of the disclosure, the co-packaged optical chip module further includes a main circuit board. The first chip is disposed on the main circuit board and is electrically connected to the main circuit board. The first chip and the first optical transmission element are located on two different sides of the main circuit board.

In an embodiment of the disclosure, the co-packaged optical chip module further includes a main circuit board, a first interposer substrate, a first driver, and a first amplifier. The first chip is disposed on the main circuit board and is electrically connected to the main circuit board. The first interposer substrate is disposed between the first light emitting and receiving unit and the main circuit board and is electrically connected to the main circuit board. The first driver is electrically connected to the at least one first light emitting element of the first light emitting and receiving unit. The first amplifier is electrically connected to the at least one first light receiving element of the first light emitting and receiving unit. The first light emitting and receiving unit, the first driver, and the first amplifier are disposed on the same first interposer substrate.

In an embodiment of the disclosure, the co-packaged optical chip module further includes a main circuit board, a first interposer substrate, a third interposer substrate, a first driver, and a first amplifier. The first chip is disposed on the main circuit board and is electrically connected to the main circuit board. The first interposer substrate is disposed between the first light emitting and receiving unit and the main circuit board and is electrically connected to the main circuit board. The third interposer substrate is electrically connected to the main circuit board and is structurally separated from the first interposer substrate. The first driver is electrically connected to the at least one first light emitting element of the first light emitting and receiving unit. The first amplifier is electrically connected to the at least one first light receiving element of the first light emitting and receiving unit. The first light emitting and receiving unit is disposed on the first interposer substrate, and the first driver and the first amplifier are disposed on the third interposer substrate.

In an embodiment of the disclosure, the co-packaged optical chip module further includes a main circuit board, a first interposer substrate, a fourth interposer substrate, a first driver, and a first amplifier. The first chip is disposed on the main circuit board and is electrically connected to the main circuit board. The first interposer substrate is disposed between the first light emitting and receiving unit and the main circuit board and is electrically connected to the main circuit board. The fourth interposer substrate is electrically connected to the main circuit board and is structurally separated from the first interposer substrate. The first driver is electrically connected to the at least one first light emitting element of the first light emitting and receiving unit. The first amplifier is electrically connected to the at least one first light receiving element of the first light emitting and receiving unit. The first light emitting and receiving unit is disposed on the first interposer substrate, and the first driver, the first amplifier, and the first chip are disposed on the fourth interposer substrate.

In an embodiment of the disclosure, the co-packaged optical chip module further includes a main circuit board, a first driver, and a first amplifier. The first chip is disposed on the main circuit board and is electrically connected to the main circuit board. The first driver is electrically connected to the at least one first light emitting element of the first light emitting and receiving unit. The first amplifier is electrically connected to the at least one first light receiving element of the first light emitting and receiving unit. The first optical transmission element, the first driver, and the first amplifier are directly disposed on the main circuit board.

### BRIEF DESCRIPTION OF THE DRAWINGS

FIG. 1 is a cross-sectional schematic view of a co-packaged optical chip module according to an embodiment of the disclosure.

FIG. 2 is a cross-sectional schematic view of a first optical transmission element according to an embodiment of the disclosure.

FIG. 3 is a cross-sectional schematic view of a second optical transmission element according to an embodiment of the disclosure.

FIG. 4 is a cross-sectional schematic view of a co-packaged optical chip module according to another embodiment of the disclosure.

FIG. 5 is a cross-sectional schematic view of a co-packaged optical chip module according to still another embodiment of the disclosure.

FIG. 6 is a cross-sectional schematic view of a co-packaged optical chip module according to yet another embodiment of the disclosure.

FIG. 7 is a cross-sectional schematic view of a co-packaged optical chip module according to an embodiment of the disclosure.

FIG. 8 is a cross-sectional schematic view of a co-packaged optical chip module according to another embodiment of the disclosure.

FIG. 9 is an enlarged schematic view of one end of a first optical transmission element according to another embodiment of the disclosure.

FIG. 10 is an enlarged schematic view of the other end of the first optical transmission element according to another embodiment of the disclosure.

FIG. 11 is a cross-sectional schematic view of a co-packaged optical chip module according to still another embodiment of the disclosure.

FIG. 12 is a cross-sectional schematic view of a co-packaged optical chip module according to yet another embodiment of the disclosure.

FIG. 13 is a cross-sectional schematic view of a co-packaged optical chip module according to an embodiment of the disclosure.

FIG. 14 is a cross-sectional schematic view of a co-packaged optical chip module according to another embodiment of the disclosure.

FIG. 15 is a cross-sectional schematic view of a co-packaged optical chip module according to still another embodiment of the disclosure.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to represent the same or similar parts.

It should be understood that when an element such as a layer, a film, a region, or a substrate is referred to as being "on" another element or "connected to" another element, the element may be directly on the another element or connected to the another element, or there may be an intermediate element. In contrast, when an element is referred to as being "directly on" another element or "directly connected to" another element, there is no intermediate element. As used herein, "connection" may refer to physical and/or electrical connection. Furthermore, "electrical connection" or "coupling" may be that there is another element between two elements.

As used herein, "about", "approximately", or "substantially" includes the stated value and an average value within an acceptable deviation range of a particular value as determined by persons skilled in the art, while taking into account the measurement in discussion and a particular amount of error (that is, the limitation of a measurement system) associated with the measurement. For example, "about" may represent being within one or more standard deviations or within ±30%, ±20%, ±15%, ±10%, or ±5% of the stated value. Furthermore, "about", "approximately", or "substantially" used herein may choose a more acceptable deviation range or standard deviation according to optical properties, etching properties, or other properties and may not apply one standard deviation to all properties.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the context of the disclosure, and should be interpreted in an idealized or overly formal manner, unless specifically defined herein.

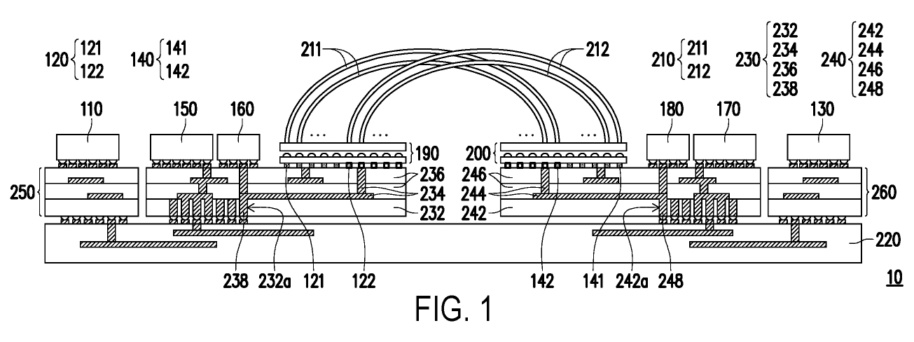

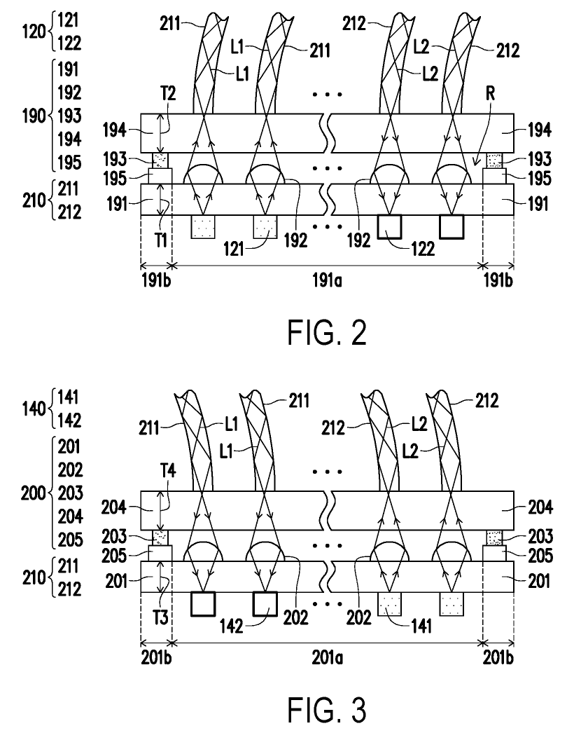

FIG. 1 is a cross-sectional schematic view of a co-packaged optical chip module according to an embodiment of the disclosure. FIG. 2 is a cross-sectional schematic view of a first optical transmission element according to an embodiment of the disclosure. FIG. 3 is a cross-sectional schematic view of a second optical transmission element according to an embodiment of the disclosure.

Please refer to FIG. 1. A co-packaged optical chip module 10 includes a first chip 110, a first light emitting and receiving unit 120, a second chip 130, and a second light emitting and receiving unit 140. The first light emitting and receiving unit 120 is electrically connected to the first chip 110 and includes at least one first light emitting element 121 and at least one first light receiving element 122. The second light emitting and receiving unit 140 is electrically connected to the second chip 130 and includes at least one second light emitting element 141 and at least one second light receiving element 142.

In some embodiments, the first light emitting and receiving unit 120 includes multiple first light emitting elements 121 arranged in an array and multiple first light receiving elements 122 arranged in an array. In some embodiments, the second light emitting and receiving unit 140 includes multiple second light emitting elements 141 arranged in an array and multiple second light receiving elements 142 arranged in an array. In some embodiments, the first light emitting element 121 and the second light emitting element 141 include micro light emitting diodes (μLED), and the first light receiving element 122 and the second light receiving element 142 include photo diodes, but the disclosure is not limited thereto.

In some embodiments, the co-packaged optical chip module 10 further includes a first driver 150, a first amplifier 160, a second driver 170, and a second amplifier 180. The first driver 150 is electrically connected to the first light emitting element 121 and the first chip 110. The first amplifier 160 is electrically connected to the first light receiving element 122 and the first chip 110. The second driver 170 is electrically connected to the second light emitting element 141 and the second chip 130. The second amplifier 180 is electrically connected to the second light receiving element 142 and the second chip 130.

Please refer to FIG. 1, FIG. 2, and FIG. 3. The first chip 110 sends a first transmission electrical signal. The first driver 150 sends a first light emitting element driving electrical signal according to the first transmission electrical signal. The first light emitting element 121 emits a first signal beam L1 according to the first light emitting element driving electrical signal. The second light receiving element 142 receives the first signal beam L1 and converts the first signal beam L1 into a first conversion electrical signal. The second amplifier 180 receives the first conversion electrical signal and amplifies the first conversion electrical signal into a first reception electrical signal. The first reception electrical signal may be transmitted to the second chip 130. The first reception electrical signal received by the second chip 130 is substantially the same as or close to the first transmission electrical signal sent by the first chip 110.

Similarly, the second chip 130 sends a second transmission electrical signal. The second driver 170 sends a second light emitting element driving electrical signal according to the second transmission electrical signal. The second light emitting element 141 emits a second signal beam L2 according to the second light emitting element driving electrical signal. The first light receiving element 122 receives the second signal beam L2 and converts the second signal beam L2 into a second conversion electrical signal. The first amplifier 160 receives the second conversion electrical signal and amplifies the second conversion electrical signal into a second reception electrical signal. The second reception electrical signal may be transmitted to the first chip 110. The second reception electrical signal received by the first chip 110 is substantially the same as or close to the second transmission electrical signal sent by the second chip 130. In this way, the signal communication between the first chip 110 and the second chip 130 may be completed using optical communication, which reduces the wire length required to transmit electrical signals and significantly reduces bandwidth delay and improves heat dissipation.

Please refer to FIG. 1 and FIG. 2. It should be noted that the co-packaged optical chip module 10 further includes a first optical transmission element 190. The co-packaged optical chip module 10 uses a special first optical transmission element 190 to complete the abovementioned optical communication. The first signal beam L1 emitted by the first light emitting element 121 of the first light emitting and receiving unit 120 is transmitted to the second light receiving element 142 of the second light emitting and receiving unit 140 through the first optical transmission element 190.

Please refer to FIG. 1, FIG. 2, and FIG. 3. In detail, in some embodiments, the co-packaged optical chip module 10 further includes a second optical transmission element 200 and an optical fiber beam 210. The second optical transmission element 200 is disposed corresponding to the second light emitting and receiving unit 140. Two ends of the optical fiber beam 210 are respectively coupled to the first optical transmission element 190 and the second optical transmission element 200. The optical fiber beam 210 includes a first optical fiber 211. The first signal beam L1 emitted by the first light emitting element 121 of the first light emitting and receiving unit 120 is sequentially transmitted through the first optical transmission element 190, the first optical fiber 211, and the second optical transmission element 200 to the second light receiving element 142 of the second light emitting and receiving unit 140.

Similarly, the second signal beam L2 emitted by the second light emitting element 141 of the second light emitting and receiving unit 140 is transmitted to the first light receiving element 122 of the first light emitting and receiving unit 120 through the first optical transmission element 190. Specifically, in some embodiments, the optical fiber beam 210 further includes a second optical fiber 212. The second signal beam L2 emitted by the second light emitting element 141 of the second light emitting and receiving unit 140 is sequentially transmitted through the second optical transmission element 200, the second optical fiber 212, and the first optical transmission element 190 to the first light receiving element 122 of the first light emitting and receiving unit 120.

Please refer to FIG. 2. The first optical transmission element 190 includes a first light transmitting base 191, at least one first micro collimating lens 192, a first sealant 193, and a second light transmitting base 194. The first light transmitting base 191 has a first working area 191a and a first peripheral area 191b surrounding the first working area 191a. The at least one first micro collimating lens 192 is disposed in the first working area 191a of the first light transmitting base 191. The first sealant 193 is disposed in the first peripheral area 191b of the first light transmitting base 191 and surrounds the at least one first micro collimating lens 192. The second light transmitting base 194 is disposed opposite to the first light transmitting base 191. The first sealant 193 connects the first light transmitting base 191 and the second light transmitting base 194.

In some embodiments, the first optical transmission element 190 includes multiple first micro collimating lenses 192, and the first micro collimating lenses 192 are respectively disposed corresponding to the first light emitting elements 121 and the first light receiving elements 122. In other words, the first micro collimating lenses 192 are respectively aligned with the first light emitting elements 121 and the first light receiving elements 122.

In some embodiments, the first optical transmission element 190 further includes a first protruding structure 195 located between the first peripheral area 191b of the first light transmitting base 191 and the second light transmitting base 194, wherein the first sealant 193 is sandwiched between the first protruding structure 195 and one of the first light transmitting base 191 and the second light transmitting base 194. The disposition of the first protruding structure 195 helps to maintain a sufficient distance between the first light transmitting base 191 and the second light transmitting base 194, thereby enabling smooth coupling of signal beams.

In some embodiments, the first protruding structure 195 and the first micro collimating lenses 192 may be formed on the first light transmitting base 191 through a lithography procedure. Then, the sealant 193 is coated on the first protruding structure 195. Next, in a near-vacuum environment, the first light transmitting base 191 and the second light transmitting base 194 are assembled, thereby completing the first optical transmission element 190. In some embodiments, the first sealant 193 may be located between the second light transmitting base 194 and the first protruding structure 195, but the disclosure is not limited thereto. In some embodiments, the first light transmitting base 191, the second light transmitting base 194, the first sealant 193, and the first protruding structure 195 may enclose to form a quasi-vacuum space R. The quasi-vacuum space R helps to reduce the degree of thermal expansion and contraction of the first optical transmission element 190, so that the first optical transmission element 190 is more suitable for installation in various environments.

In some embodiments, the first light transmitting base 191 of the first optical transmission element 190 is closer to the first light emitting and receiving unit 120 than the second light transmitting base 194 of the first optical transmission element 190, and a thickness T1 of the first light transmitting base 191 is less than a thickness T2 of the second light transmitting base 194. The first light transmitting base 191 having the thinner thickness T1 helps to reduce the degree of divergence of the first signal beam L1, thereby enabling the first signal beam L1 to be better coupled into the first optical fiber 211.

Please refer to FIG. 3. The second optical transmission element 200 includes a third light transmitting base 201, at least one second micro collimating lens 202, a second sealant 203, and a fourth light transmitting base 204. The third light transmitting base 201 has a first working area 201a and a first peripheral area 201b surrounding the first working area 201a. The at least one first micro collimating lens 202 is disposed on the first working area 201a of the third light transmitting base 201. The second sealant 203 is disposed on the first peripheral area 201b of the third light transmitting base 201 and surrounds the at least one second micro collimating lens 202. The fourth light transmitting base 204 is disposed opposite to the first light transmitting base 201. The second sealant 203 connects the third light transmitting base 201 and the fourth light transmitting base 204.

In some embodiments, the second optical transmission element 200 includes multiple second micro collimating lenses 202, and the second micro collimating lenses 202 of the second optical transmission element 200 are respectively disposed corresponding to the second light emitting elements 141 and the second light receiving elements 142. In other words, the second micro collimating lenses 202 are respectively aligned with the second light emitting elements 141 and the second light receiving elements 142.

In some embodiments, the second optical transmission element 200 further includes a second protruding structure 205 located between the first peripheral area 201b of the third light transmitting base 201 and the fourth light transmitting base 204, wherein the second sealant 203 is sandwiched between the second protruding structure 205 and one of the third light transmitting base 201 and the fourth light transmitting base 204.

In some embodiments, the third light transmitting base 201 of the second optical transmission element 200 is closer to the second light emitting and receiving unit 140 than the fourth light transmitting base 204 of the second optical transmission element 200, and a thickness T3 of the third light transmitting base 201 is less than a thickness T4 of the fourth light transmitting base 204. The third light transmitting base 201 having the thinner thickness T3 helps to reduce the degree of divergence of the second signal beam L2, thereby enabling the second signal beam L2 to be better coupled into the second optical fiber 212.

Please refer to FIG. 1. In some embodiments, the co-packaged optical chip module 10 further includes a main circuit board 220. The first chip 110, the first driver 150, the first amplifier 160, the first light emitting and receiving unit 120, the second light emitting and receiving unit 140, the second amplifier 180, the second driver 170, and the second chip 130 are disposed on the main circuit board 220 and are electrically connected to the main circuit board 220.

In some embodiments, the co-packaged optical chip module 10 may optionally include a first interposer substrate 230 disposed between the first light emitting and receiving unit 120 and the main circuit board 220. The first interposer substrate 230 includes a base 232, at least one conductive layer 234, and at least one dielectric layer 236. The base 232 is disposed on the main circuit board 220. The at least one conductive layer 234 is disposed on the base 232 and is electrically connected to the main circuit board 220. The at least one dielectric layer 236 covers the at least one conductive layer 234. The first light emitting elements 121 and the first light receiving elements 122 are bonded to the at least one conductive layer 234 of the first interposer substrate 230. In some embodiments, the base 232 may be optionally light transmissive. In some embodiments, the material of the base 232 may be glass, quartz, or other appropriate materials. However, the disclosure is not limited thereto. In some embodiments, the base 232 may also be non-light transmissive.

In some embodiments, the base 232 of the first interposer substrate 230 has multiple through holes 232a. The first interposer substrate 230 further includes multiple conductive objects 238. The conductive objects 238 are respectively disposed in the through holes 232a of the base 232. The conductive objects 238 are electrically connected to the at least one conductive layer 234 of the first interposer substrate 230 and the main circuit board 220.

In some embodiments, the first light emitting and receiving unit 120, the first driver 150, and the first amplifier 160 may be optionally disposed on the same first interposer substrate 230, wherein the first driver 150 and the first amplifier 160 may be electrically connected to the main circuit board 220 and the first chip 110 through the first interposer substrate 230, but the disclosure is not limited thereto.

In some embodiments, the co-packaged optical chip module 10 may further optionally include a second interposer substrate 240 disposed between the second light emitting and receiving unit 140 and the main circuit board 220 and electrically connecting the second light emitting and receiving unit 140 and the main circuit board 220. The second interposer substrate 240 includes a base 242, at least one conductive layer 244, and at least one dielectric layer 246. The base 242 is disposed on the main circuit board 220. The at least one conductive layer 244 is disposed on the base 242 and is electrically connected to the main circuit board 220. The at least one dielectric layer 246 covers the at least one conductive layer 244. The second light emitting elements 141 and the second light receiving elements 142 are bonded to the at least one conductive layer 244 of the second interposer substrate 240. In some embodiments, the base 242 may be optionally light transmissive. In some embodiments, the material of the base 242 may be glass, quartz, or other appropriate materials. However, the disclosure is not limited thereto. In some embodiments, the base 242 may also be non-light transmissive.

In some embodiments, the base 242 of the second interposer substrate 240 has multiple through holes 242a. The second interposer substrate 240 further includes multiple conductive objects 248. The conductive objects 248 are respectively disposed in the through holes 242a of the base 242 of the second interposer substrate 240. The conductive objects 248 are electrically connected to the at least one conductive layer 244 of the second interposer substrate 240 and the main circuit board 220.

In some embodiments, the second light emitting and receiving unit 140, the second driver 170, and the second amplifier 180 may be optionally disposed on the same second interposer substrate 240, wherein the second driver 170 and the second amplifier 180 may be electrically connected to the main circuit board 220 and the second chip 130 through the second interposer substrate 240, but the disclosure is not limited thereto.

In some embodiments, the co-packaged optical chip module 10 may further optionally include an interposer substrate 250 disposed between the first chip 110 and the main circuit board 220 and structurally separated from the first interposer substrate 230. The first chip 110 may be electrically connected to the main circuit board 220 through the interposer substrate 250.

In some embodiments, the co-packaged optical chip module 10 may further optionally include an interposer substrate 260 disposed between the second chip 130 and the main circuit board 220 and structurally separated from the second interposer substrate 240. The second chip 130 may be electrically connected to the main circuit board 220 through the second interposer substrate 240.

It must be noted here that the following embodiments continue to use the reference numerals and some content of the abovementioned embodiment, wherein the same numerals are adopted to represent the same or similar elements, and the description of the same technical content is omitted. Reference may be made to the abovementioned embodiment for the description of the omitted part, which will not be repeated in the following embodiments.

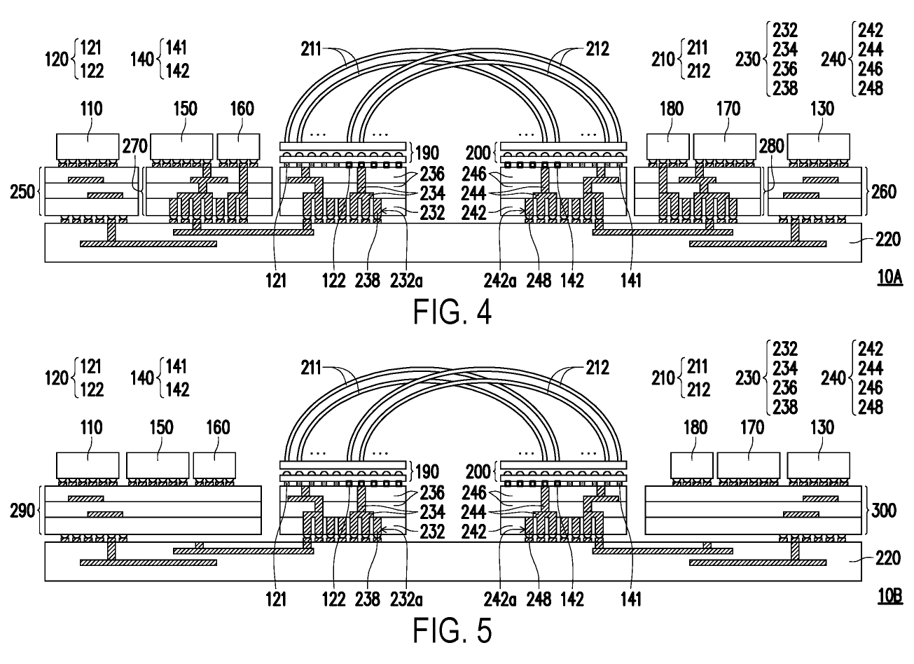

FIG. 4 is a cross-sectional schematic view of a co-packaged optical chip module according to another embodiment of the disclosure. A co-packaged optical chip module 10A of FIG. 4 is similar to the co-packaged optical chip module 10 of FIG. 1. The difference between the two is that in the embodiment of FIG. 4, the first light emitting and receiving unit 120 is disposed on the first interposer substrate 230, but the first driver 150 and the first amplifier 160 are disposed on a third interposer substrate 270 separated from the first interposer substrate 230 and the interposer substrate 250, wherein the third interposer substrate 270 is electrically connected to the main circuit board 220; and the second light emitting and receiving unit 140 is disposed on the second interposer substrate 240, but the second driver 170 and the second amplifier 180 are disposed on another interposer substrate 280 separated from the second interposer substrate 240 and the interposer substrate 260, wherein the interposer substrate 280 is electrically connected to the main circuit board 220.

FIG. 5 is a cross-sectional schematic view of a co-packaged optical chip module according to still another embodiment of the disclosure. A co-packaged optical chip module 10B of FIG. 5 is similar to the co-packaged optical chip module 10 of FIG. 1. The difference between the two is that in the embodiment of FIG. 5, the first light emitting and receiving unit 120 is disposed on the first interposer substrate 230, but the first driver 150, the first amplifier 160, and the first chip 110 are disposed on a fourth interposer substrate 290 separated from the first interposer substrate 230; and the second light emitting and receiving unit 140 is disposed on the second interposer substrate 240, but the second driver 170, the second amplifier 180, and the second chip 130 are disposed on an interposer substrate 300 separated from the second interposer substrate 240.

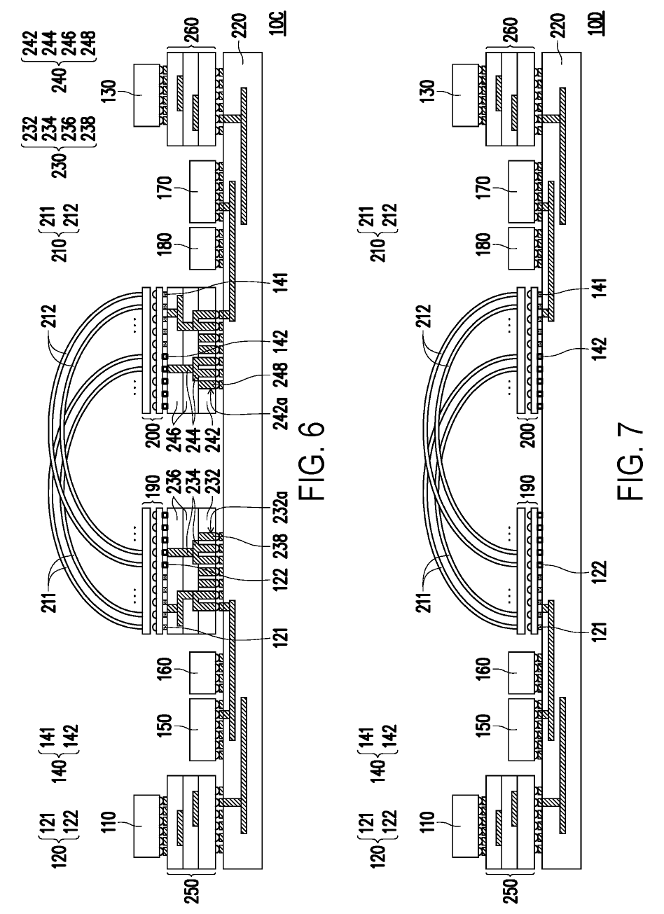

FIG. 6 is a cross-sectional schematic view of a co-packaged optical chip module according to yet another embodiment of the disclosure. A co-packaged optical chip module 10C of FIG. 6 is similar to the co-packaged optical chip module 10 of FIG. 1. The difference between the two is that in the embodiment of FIG. 6, the first driver 150, the first amplifier 160, the second driver 170, and the second amplifier 180 are directly disposed on the main circuit board 220.

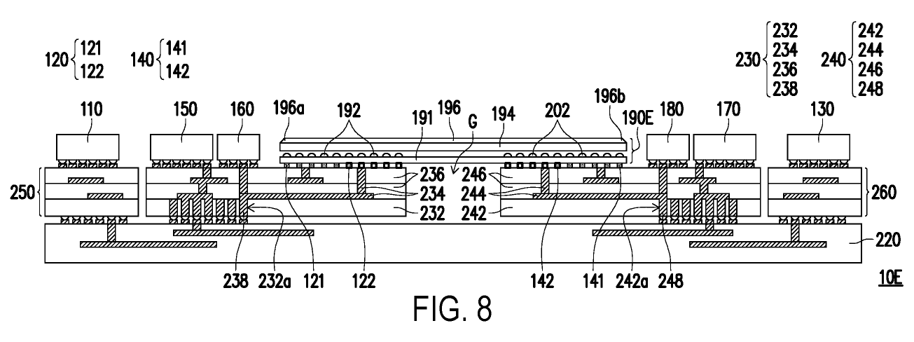

FIG. 7 is a cross-sectional schematic view of a co-packaged optical chip module according to an embodiment of the disclosure. A co-packaged optical chip module 10D of FIG. 7 is similar to the co-packaged optical chip module 10 of FIG. 1. The difference between the two is that in the embodiment of FIG. 7, the first optical transmission element 190, the first driver 150, the first amplifier 160, the second optical transmission element 200, the second driver 170, and the second amplifier 180 are all directly disposed on the main circuit board 220.

FIG. 8 is a cross-sectional schematic view of a co-packaged optical chip module according to another embodiment of the disclosure. A co-packaged optical chip module 10E of FIG. 8 is similar to the co-packaged optical chip module 10 of FIG. 1. The difference between the two is that a first optical transmission element 190E of the co-packaged optical chip module 10E of FIG. 8 is different from the first optical transmission element 190 of the co-packaged optical chip module 10 of FIG. 1. The first optical transmission element 190E of FIG. 8 may replace the functions of the first optical transmission element 190, the second optical transmission element 200, and the optical fiber beam 210 of FIG. 1.

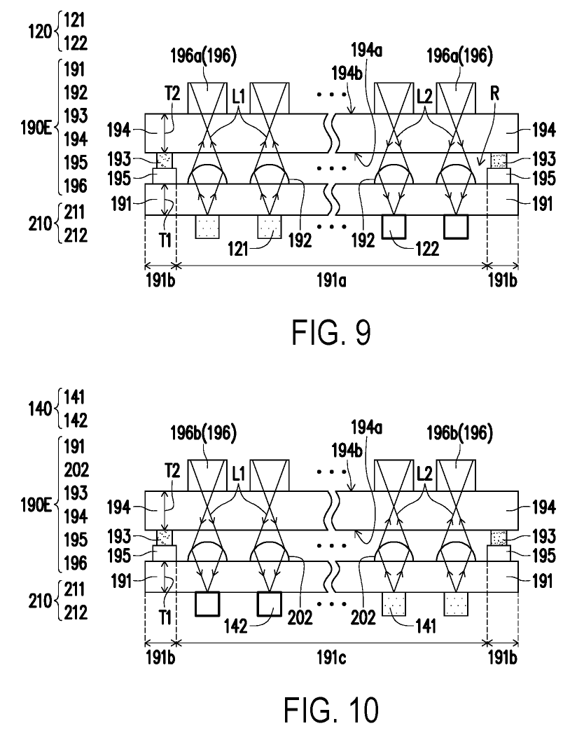

FIG. 9 is an enlarged schematic view of one end of a first optical transmission element according to another embodiment of the disclosure. FIG. 10 is an enlarged schematic view of the other end of the first optical transmission element according to another embodiment of the disclosure. Please refer to FIG. 8, FIG. 9, and FIG. 10. In the embodiment, the first optical transmission element 190E includes the first light transmitting base 191, the at least one first micro collimating lens 192, the first sealant 193, the second light transmitting base 194, the at least one second micro collimating lens 202, and at least one waveguide 196. The first light transmitting base 191 has the first working area 191a and the first peripheral area 191b surrounding the first working area 191a. The at least one first micro collimating lens 192 is disposed on the first working area 191a of the first light transmitting base 191. The first sealant 193 is disposed on the first peripheral area 191b of the first light transmitting base 191 and surrounds the at least one first micro collimating lens 192. The second light transmitting base 194 is disposed opposite to the first light transmitting base 191. The first sealant 193 connects the first light transmitting base 191 and the second light transmitting base 194. The first light transmitting base 191 further has a second working area 191c located outside the first working area 191a. The at least one second micro collimating lens 202 is disposed on the second working area 191c of the first light transmitting base 191. The first sealant 193 further surrounds the at least one second micro collimating lens 202. The second light transmitting base 194 of the first optical transmission element 190E has an inner surface 194a and an outer surface 194b. The inner surface 194a faces the at least one first micro collimating lens 192. The outer surface 194b is opposite to the inner surface 194a. The at least one waveguide 196 is disposed on the outer surface 194b of the second light transmitting base 194. Two ends 196a and 196b of the at least one waveguide 196 respectively correspond to the at least one first micro collimating lens 192 and the at least one second micro collimating lens 202. In the embodiment, there is a gap G between the first light emitting and receiving unit 120 and the second light emitting and receiving unit 140, and the at least one waveguide 196 of the first optical transmission element 190E spans across the gap G.

In the embodiment, the co-packaged optical chip module 10E may complete optical communication using the first optical transmission element 190E without the second optical transmission element 200 and the optical fiber beam 210 of FIG. 1.

Specifically, in the embodiment, the first chip 110 sends the first transmission electrical signal. The first driver 150 sends the first light emitting element driving electrical signal according to the first transmission electrical signal. The first light emitting element 121 emits the first signal beam L1 according to the first light emitting element driving electrical signal. The first signal beam L1 is transmitted to the second micro collimating lens 202 using the waveguide 196 of the first optical transmission element 190E and is then received by the second light receiving element 142. The second light receiving element 142 receives the first signal beam L1 and converts the first signal beam L1 into the first conversion electrical signal. The second amplifier 180 receives the first conversion electrical signal and amplifies the first conversion electrical signal into the first reception electrical signal. The first reception electrical signal may be transmitted to the second chip 130. The first reception electrical signal received by the second chip 130 is substantially the same as or close to the first transmission electrical signal sent by the first chip 110.

The second chip 130 sends the second transmission electrical signal. The second driver 170 sends the second light emitting element driving electrical signal according to the second transmission electrical signal. The second light emitting element 141 emits the second signal beam L2 according to the second light emitting element driving electrical signal. The second signal beam L2 is transmitted to the first micro collimating lens 192 using the waveguide 196 of the first optical transmission element 190E and is then received by the first light receiving element 122. The first light receiving element 122 receives the second signal beam L2 and converts the second signal beam L2 into the second conversion electrical signal. The first amplifier 160 receives the second conversion electrical signal and amplifies the second conversion electrical signal into the second reception electrical signal. The second reception electrical signal may be transmitted to the first chip 110. The second reception electrical signal received by the first chip 110 is substantially the same as or close to the second transmission electrical signal sent by the second chip 130.

The signal communication between the first chip 110 and the second chip 130 may be completed using optical communication by first optical transmission element 190E, which not only reduces the wire length required to transmit electrical signals and significantly reduces bandwidth delay and improves heat dissipation, but also reduces the assembly complexity of the co-packaged optical chip module 10E.

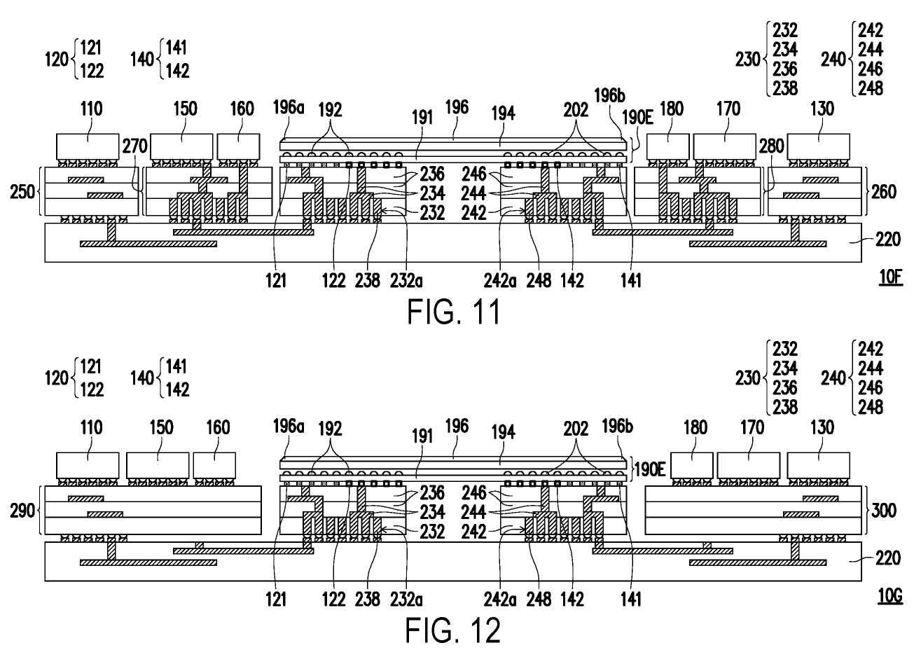

FIG. 11 is a cross-sectional schematic view of a co-packaged optical chip module according to still another embodiment of the disclosure. A co-packaged optical chip module 10F of FIG. 11 is similar to the co-packaged optical chip module 10E of FIG. 8. The difference between the two is that in the embodiment of FIG. 11, the first light emitting and receiving unit 120 is disposed on the first interposer substrate 230, but the first driver 150 and the first amplifier 160 are disposed on the third interposer substrate 270 separated from the first interposer substrate 230 and the interposer substrate 250, wherein the third interposer substrate 270 is electrically connected to the main circuit board 220; and the second light emitting and receiving unit 140 is disposed on the second interposer substrate 240, but the second driver 170 and the second amplifier 180 are disposed on another interposer substrate 280 separated from the second interposer substrate 240 and the interposer substrate 260, wherein the interposer substrate 280 is electrically connected to the main circuit board 220.

FIG. 12 is a cross-sectional schematic view of a co-packaged optical chip module according to yet another embodiment of the disclosure. A co-packaged optical chip module 10G of FIG. 12 is similar to the co-packaged optical chip module 10E of FIG. 8. The difference between the two is that in the embodiment of FIG. 12, the first light emitting and receiving unit 120 is disposed on the first interposer substrate 230, but the first driver 150, the first amplifier 160, and the first chip 110 are disposed on the fourth interposer substrate 290 separated from the first interposer substrate 230. The second light emitting and receiving unit 140 is disposed on the second interposer substrate 240, but the second driver 170, the second amplifier 180, and the second chip 130 are disposed on the interposer substrate 300 separated from the second interposer substrate 240.

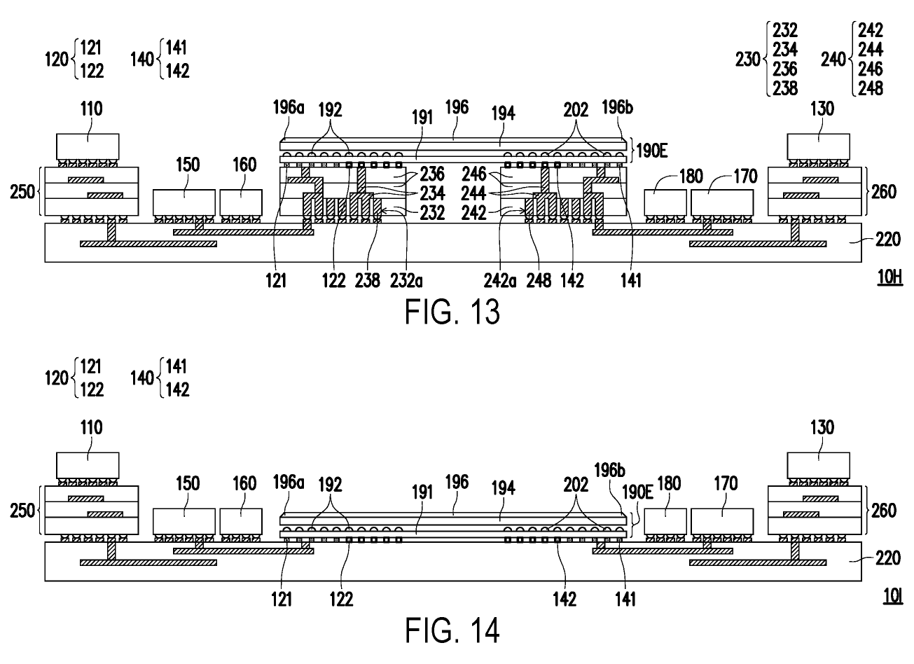

FIG. 13 is a cross-sectional schematic view of a co-packaged optical chip module according to an embodiment of the disclosure. A co-packaged optical chip module 10H of FIG. 13 is similar to the co-packaged optical chip module 10E of FIG. 8. The difference between the two is that in the embodiment of FIG. 13, the first driver 150, the first amplifier 160, the second driver 170, and the second amplifier 180 are directly disposed on the main circuit board 220.

FIG. 14 is a cross-sectional schematic view of a co-packaged optical chip module according to another embodiment of the disclosure. A co-packaged optical chip module 10I of FIG. 14 is similar to the co-packaged optical chip module 10E of FIG. 8. The difference between the two is that in the embodiment of FIG. 14, the first optical transmission element 190E, the first driver 150, the first amplifier 160, the second driver 170, and the second amplifier 180 are all directly disposed on the main circuit board 220.

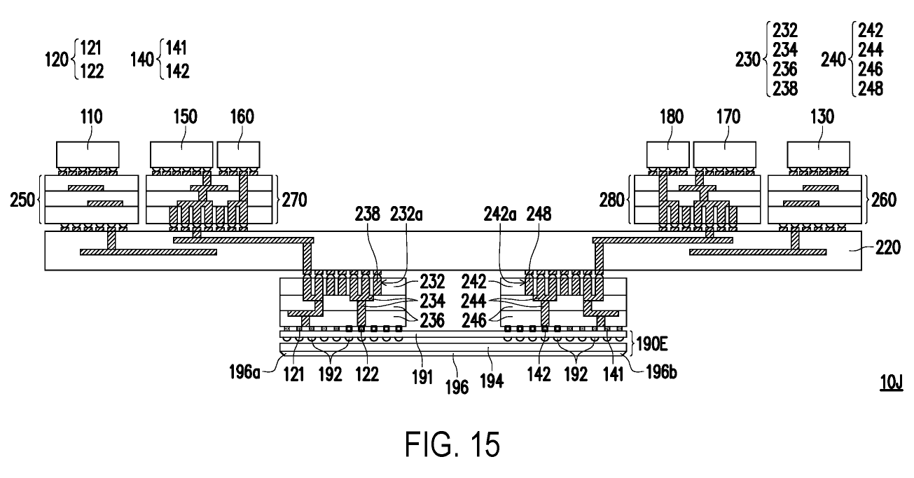

FIG. 15 is a cross-sectional schematic view of a co-packaged optical chip module according to still another embodiment of the disclosure. A co-packaged optical chip module 10J of FIG. 15 is similar to the co-packaged optical chip module 10F of FIG. 11. The difference between the two is that in the embodiment of FIG. 15, the first chip 110 and the first optical transmission element 190E are respectively located on two different sides of the main circuit board 220. The first light emitting and receiving unit 120, the second light emitting and receiving unit 140, and the first optical transmission element 190E are disposed on the same side of the main circuit board 220. By disposing the first optical transmission element 190E on a back side of the main circuit board 220, the disposition of the first optical transmission element 190E is not limited by the original wiring of the main circuit board 220.

What is claimed is:

1. A co-packaged optical chip module, comprising:
a first chip;
a first light emitting and receiving unit, electrically connected to the first chip, wherein the first light emitting and receiving unit comprises at least one first light emitting element and at least one first light receiving element;
a second chip;
a second light emitting and receiving unit, electrically connected to the second chip, wherein the second light emitting and receiving unit comprises at least one second light emitting element and at least one second light receiving element; and
a first optical transmission element, wherein the at least one first light emitting element of the first light emitting and receiving unit is configured to emit a first signal beam, and the first signal beam is transmitted to the at least one second light receiving element of the second light emitting and receiving unit through the first optical transmission element, wherein the first optical transmission element comprises:
a first light transmitting base, having a first working area and a first peripheral area surrounding the first working area;
at least one first micro collimating lens, disposed on the first working area of the first light transmitting base;
a first sealant, disposed on the first peripheral area of the first light transmitting base and surrounding the at least one first micro collimating lens; and
a second light transmitting base, disposed opposite to the first light transmitting base, wherein the first sealant connects the first light transmitting base and the second light transmitting base.

2. The co-packaged optical chip module according to claim 1, wherein the at least one first light emitting element comprises a plurality of first light emitting elements, the at least one first light receiving element comprises a plurality of first light receiving elements, the at least one first micro collimating lens comprises a plurality of first micro collimating lenses, and the first micro collimating lenses of the first optical transmission element are respectively disposed corresponding to the first light emitting elements and the first light receiving elements.

3. The co-packaged optical chip module according to claim 1, wherein the first optical transmission element further comprises:
a first protruding structure, located between the first peripheral area of the first light transmitting base and the second light transmitting base, wherein the first sealant is sandwiched between the first protruding structure and one of the first light transmitting base and the second light transmitting base.

4. The co-packaged optical chip module according to claim 1, wherein the first light transmitting base, the second light transmitting base, and the first sealant enclose to form a quasi-vacuum space.

5. The co-packaged optical chip module according to claim 1, wherein the first light transmitting base is closer to the first light emitting and receiving unit than the second light transmitting base, and a thickness of the first light transmitting base is less than a thickness of the second light transmitting base.

6. The co-packaged optical chip module according to claim 1, further comprising:
a main circuit board, wherein the first chip is disposed on the main circuit board and is electrically connected to the main circuit board; and
a first interposer substrate, disposed between the first light emitting and receiving unit and the main circuit board, the first interposer substrate comprising:
a base, disposed on the main circuit board;
at least one conductive layer, disposed on the base and electrically connected to the main circuit board; and
at least one dielectric layer, covering the at least one conductive layer, wherein the first light emitting elements and the first light receiving elements are bonded to the at least one conductive layer of the first interposer substrate.

7. The co-packaged optical chip module according to claim 6, wherein the base of the first interposer substrate has a plurality of through holes, and the first interposer substrate further comprises:
a plurality of conductive objects, respectively disposed in the through holes of the base of the first interposer substrate, wherein the conductive objects are electrically connected to the at least one conductive layer of the first interposer substrate and the main circuit board.

8. The co-packaged optical chip module according to claim 1, further comprising:
a second optical transmission element, comprising:
a third light transmitting base, having a first working area and a first peripheral area surrounding the first working area;
at least one second micro collimating lens, disposed on the first working area of the third light transmitting base;
a second sealant, disposed on the first peripheral area of the third light transmitting base and surrounding the at least one second micro collimating lens; and
a fourth light transmitting base, disposed opposite to the third light transmitting base, wherein the second sealant connects the third light transmitting base and the fourth light transmitting base; and
an optical fiber beam, wherein two ends of the optical fiber beam are respectively coupled to the first optical transmission element and the second optical transmission element.

9. The co-packaged optical chip module according to claim 1, wherein the first light transmitting base further has a second working area located outside the first working area, and the first optical transmission element further comprises:
at least one second micro collimating lens, disposed on the second working area of the first light transmitting base, wherein the first sealant further surrounds the at least one second micro collimating lens; and
at least one waveguide, wherein the second light transmitting base of the first optical transmission element has an inner surface and an outer surface, the inner surface faces the at least one first micro collimating lens, the outer surface is opposite to the inner surface, the at least one waveguide is disposed on the outer surface of the second light transmitting base, and two ends of the at least one waveguide respectively correspond to the at least one first micro collimating lens and the at least one second micro collimating lens.

10. The co-packaged optical chip module according to claim 9, wherein there is a gap between the first light emitting and receiving unit and the second light emitting and receiving unit, and the at least one waveguide of the first optical transmission element spans across the gap.

11. The co-packaged optical chip module according to claim 9, further comprising:
a main circuit board, wherein the first chip is disposed on the main circuit board and is electrically connected to the main circuit board, and the first chip and the first optical transmission element are respectively located on two different sides of the main circuit board.

12. The co-packaged optical chip module according to claim 1, further comprising:
a main circuit board, wherein the first chip is disposed on the main circuit board and is electrically connected to the main circuit board;
a first interposer substrate, disposed between the first light emitting and receiving unit and the main circuit board and electrically connected to the main circuit board;
a first driver, electrically connected to the at least one first light emitting element of the first light emitting and receiving unit; and
a first amplifier, electrically connected to the at least one first light receiving element of the first light emitting and receiving unit;
wherein the first light emitting and receiving unit, the first driver, and the first amplifier are disposed on the same first interposer substrate.

13. The co-packaged optical chip module according to claim 1, further comprising:
a main circuit board, wherein the first chip is disposed on the main circuit board and is electrically connected to the main circuit board;
a first interposer substrate, disposed between the first light emitting and receiving unit and the main circuit board and electrically connected to the main circuit board;
a third interposer substrate, electrically connected to the main circuit board and structurally separated from the first interposer substrate;
a first driver, electrically connected to the at least one first light emitting element of the first light emitting and receiving unit; and
a first amplifier, electrically connected to the at least one first light receiving element of the first light emitting and receiving unit;
wherein the first light emitting and receiving unit is disposed on the first interposer substrate, and the first driver and the first amplifier are disposed on the third interposer substrate.

14. The co-packaged optical chip module according to claim 1, further comprising:
a main circuit board, wherein the first chip is disposed on the main circuit board and is electrically connected to the main circuit board;
a first interposer substrate, disposed between the first light emitting and receiving unit and the main circuit board and electrically connected to the main circuit board;
a fourth interposer substrate, electrically connected to the main circuit board and structurally separated from the first interposer substrate;
a first driver, electrically connected to the at least one first light emitting element of the first light emitting and receiving unit; and
a first amplifier, electrically connected to the at least one first light receiving element of the first light emitting and receiving unit;
wherein the first light emitting and receiving unit is disposed on the first interposer substrate, and the first driver, the first amplifier, and the first chip are disposed on the fourth interposer substrate.

15. The co-packaged optical chip module according to claim 1, further comprising:
a main circuit board, wherein the first chip is disposed on the main circuit board and is electrically connected to the main circuit board;
a first driver, electrically connected to the at least one first light emitting element of the first light emitting and receiving unit; and
a first amplifier, electrically connected to the at least one first light receiving element of the first light emitting and receiving unit;
wherein the first optical transmission element, the first driver, and the first amplifier are directly disposed on the main circuit board.

16. A co-packaged optical chip module, comprising:
a first chip;
a first light emitting and receiving unit, electrically connected to the first chip, wherein the first light emitting and receiving unit comprises at least one first light emitting element and at least one first light receiving element;
a second chip;
a second light emitting and receiving unit, electrically connected to the second chip, wherein the second light emitting and receiving unit comprises at least one second light emitting element and at least one second light receiving element; and
a first optical transmission element, wherein the at least one first light emitting element of the first light emitting and receiving unit is configured to emit a first signal beam, and the first signal beam is transmitted to the at least one second light receiving element of the second light emitting and receiving unit through the first optical transmission element, wherein the first optical transmission element comprises:
a first light transmitting base, having a first working area and a first peripheral area surrounding the first working area;
a first sealant, disposed on the first peripheral area of the first light transmitting base; and
a second light transmitting base, disposed opposite to the first light transmitting base, wherein the first sealant connects the first light transmitting base and the second light transmitting base, the first light transmitting base is closer to the first light emitting and receiving unit than the second light transmitting base, and a thickness of the first light transmitting base is less than a thickness of the second light transmitting base.
